(19) United States
(12) Patent Application Publication
(10) Pub. No.: US 2017/0108541 A1
(43) Pub. Date: Apr. 20, 2017

(54) DIGITAL PROTECTION RELAY

(71) Applicant: Mitsubishi Electric Corporation, Chiyoda-ku, Tokyo (JP)

(72) Inventor: Shigetoo ODA, Chiyoda-ku, Tokyo (JP)

(73) Assignee: Mitsubishi Electric Corporation, Chiyoda-ku, Tokyo, OT (JP)

(21) Appl. No.: 15/316,088

(22) PCT Filed: Jun. 13, 2014
(86) PCT No.: PCT/JP2014/065781

§ 371 Date: Dec. 2, 2016

(51) Int. Cl. G01R 19/165; H02H 3/02; G01R 23/15

(52) U.S. Cl. CPC G01R 19/16547; G01R 23/15; H02H 3/02

(57) ABSTRACT

A digital protection relay includes: an input conversion unit configured to receive a signal showing a quantity of electricity in an electric power system as an analog signal; and an analog-to-digital conversion unit. The digital protection relay is configured to cause a processing control unit to perform protection calculation based on the digital signal. The processing control unit functions as: a protection calculation unit configured to perform the protection calculation using an offset voltage value; an input data acquisition unit configured to sequentially acquire input data, which is converted into a digital signal, in accordance with sampling timing; and an offset value calculation unit configured to calculate the offset voltage value based on sampling values at a timing at which a change occurs in a polarity of a differential amount among the input data in at least one cycle.

### TECHNICAL FIELD

The present invention relates to a digital protection relay, and particularly to a technique for appropriately correcting an error in input data resulting from an analog device for acquiring information about at least a current or a voltage as an analog signal from an electric power system.

### BACKGROUND ART

In order to stabilize the operation of an electric power system, various types of devices are used for detecting an accident or an abnormality having occurred in the electric power system. For example, from a current transformer (CT), a potential transformer (PT) or a voltage transformer (VT) or the like, a digital protection relay acquires a quantity of electricity such as a voltage value and a current value in the system as an analog signal by using an analog input element. The digital protection relay samples the analog signal in a prescribed cycle, and converts the sampled analog signal into digital data by an AD (Analog-to-Digital) converter. The digital protection relay uses this digital data to perform protection relay calculation, thereby determining whether a failure occurs or not in the system. For example, when the digital protection relay detects a failed section, it performs a protecting operation such as tripping of a circuit breaker in order to separate the failed section from the system. Thereby, an immediate action can be taken, for example, by separating the failed section from the electric power system, and the like.

The analog input circuit of such a digital protection relay is typically formed of a transformer, an analog filter, a sample hold circuit, a multiplexer, an AD converter, and the like. The transformer receives an input of quantities of electricity such as a voltage value and a current value in the system and converts the received input into a signal level appropriate for the digital protection relay. The analog filter removes a high frequency noise component or the like that is superimposed on the input component of the commercial frequency. The sample hold circuit holds a signal from which an unnecessary frequency component has been removed by the analog filter. The analog input circuit may receive an input of quantities of electricity through a plurality of channels, in which case a plurality of groups each including a transformer, an analog filter and a sample hold circuit may be arranged. The multiplexer performs time-division multiplexing of the signals on the plurality of channels output from the sample hold circuit, and outputs the resultant signal to the AD converter. The AD converter converts the time-division multiplexed analog signal into a digital signal.

The analog devices forming such an analog input circuit are individually different, and also, there are variations in the components of an amplifier forming such an analog device, thereby generating a minute direct-current (DC) voltage (offset voltage) of, for example, about several mV to several 10 mV even if an input voltage is zero. Accordingly, the offset voltage is superimposed on the input signal in the course in which the digital protection relay converts, into digital data, the quantity of electricity input into the analog input circuit. Consequently, in order for the digital protection relay to perform protection relay calculation with high accuracy, the offset voltage needs to be removed before performing calculation.

The technique for removing such an offset voltage is disclosed, for example, in Japanese Patent Laying-Open No. 1-198213 (PTD 1). While paying attention to the feature that the input data is a sinusoidal wave that oscillates at a certain constant voltage level as a reference, PTD 1 discloses a technique for integrating digital data output from the AD converter for a sufficiently long time period as compared with the frequency of the electric power system, to thereby calculate an average value of the integration results as an offset voltage value.

### CITATION LIST

### Patent Document

PTD 1: Japanese Patent Laying-Open No. 1-198213

### SUMMARY OF INVENTION

### Technical Problem

According to the technique disclosed in PTD 1, however, for removing an offset voltage, the integrated amount of the input signal in a sufficiently long time period is used as compared with the frequency of an input signal. Consequently, integration of data requires a relatively long time period. The time period of data integration is set to be an integer cycle of the input frequency to average steady alternating-current (AC) components, thereby still allowing removal of the offset voltage. However, the sampling cycle is generally set to be constant without depending on the input frequency. Accordingly, when the input frequency deviates from the rated frequency, the data acquired by sampling is to deviate from the integer cycle, thereby causing an average error in the maximum half wave. Particularly, at startup of a power generator, the power generator may be protected with time of about several tens of minutes until the frequency of several Hz rises to the rated frequency. In this case, a long integration time period is required for suppressing an error caused by deviation of the input frequency from the rated frequency to be a negligible level. This poses a problem that it cannot be expected to achieve accurate protection relay calculation during a time period from startup of the power generator until a lapse of a long integration time period.

Accordingly, there is a demand for a technique for calculating and updating an offset voltage value used for removing an offset voltage in a shorter time period. In consideration of the above-described problem, the present disclosure aims to provide a digital protection relay for calculating and updating an offset value in a relatively short time period also in a time period, for example, during which the frequency changes from a low frequency of about 5 Hz to the rated frequency.

### Solution to Problem

As an analog input circuit, a digital protection relay according to one embodiment includes: an input conversion unit configured to receive a signal showing a quantity of electricity in an electric power system as an analog signal; and an analog-to-digital conversion unit configured to convert the analog signal into a digital signal. The digital protection relay is configured to cause a control unit to perform protection calculation based on the digital signal converted by the analog-to-digital conversion unit. The control unit includes: a protection calculation unit configured to perform the protection calculation using an offset voltage value; an acquisition unit configured to sequentially acquire input data, which is converted into a digital signal by the analog-to-digital conversion unit, in accordance with sampling timing; and an offset value calculation unit configured to, based on a differential amount between sampling values, calculate the offset voltage value based on the sampling values within a time period in which a change occurs in a polarity of the differential amount among the input data in at least one cycle.

### Advantageous Effects of Invention

According to the digital protection relay in one embodiment described above, the offset voltage value is calculated based on the sampling value within a time period in which a change occurs in the polarity of the differential amount between the sampling values sampled in at least one cycle. Accordingly, the digital protection relay can calculate an offset voltage value, for example, using the sampling value in fewer cycles such as one cycle as compared with the conventional technique irrespective of the frequency of the input signal. Thus, the digital protection relay can calculate and update an offset value in a short time period, for example, of about several seconds.

The foregoing and other objects, features, aspects and advantages of the present invention will become more apparent from the following detailed description of the present invention when taken in conjunction with the accompanying drawings.

### BRIEF DESCRIPTION OF DRAWINGS

FIG. 1 is a block diagram showing the configuration of a digital protection relay according to the present embodiment.

FIG. 2 is a diagram showing the sampling timing and an AC input of a current or a voltage received by a digital protection relay 10.

FIG. 3 shows a time period in which a change occurs in the polarity of a differential value ΔV(t) of input data at each sampling timing.

FIG. 4 is a flowchart showing a process of correcting an offset value by digital protection relay 10.

FIG. 5 is a diagram showing a process for detecting a maximum value and a minimum value from among sampling values.

FIG. 6 is a diagram showing an example of sampling at a low frequency.

FIG. 7 is a diagram showing the configuration of a digital protection relay 10-2 in the second embodiment.

FIG. 8 is a flowchart illustrating the operation of digital protection relay 10-2 in the second embodiment.

FIG. 9 is a diagram showing the relation between an electrical angle and the magnitude of a differential amount between the sampling values.

FIG. 10 is a diagram showing a process for detecting the maximum value and the minimum value from among the sampling values.

### DESCRIPTION OF EMBODIMENTS

The embodiments of the present invention will be hereinafter described with reference to the accompanying drawings. In the following description, the same components are designated by the same reference characters. Names and functions thereof are also the same. Accordingly, the detailed description thereof will not be repeated.

<Calculation of Offset Value by Digital Protection Relay in Related Art>

First, for the purpose of comparison with a digital protection relay in the present embodiment, an explanation will be given with regard to an example of the time period required for calculating an offset value by a digital protection relay in the related art.

The analog signal input into a digital protection relay is a sinusoidal wave that oscillates at a certain fixed voltage level as a reference. Accordingly, the digital protection relay in the related art accumulates digital data of the input data in a sufficiently long time period as compared with the frequency in the electric power system, to average the integration results of the accumulated digital data, thereby calculating an offset voltage value. In this case, for example, assuming that the rated frequency is set at 50 Hz, that the sampling frequency is set at 600 Hz (the sampling cycle is set at an electrical angle 30° of the rated frequency), and that the sample number in the integration time period is set at a sample number “2¹⁶”, the integration time period is about 109 seconds based on the equation: integration time period=(sample number/sampling frequency)=(2¹⁶/600). Accordingly, in the digital protection relay of the related art, the offset voltage value is calculated for every about 109 seconds.

When performing a trial calculation of the integration time period in the case where the input frequency gradually increases from a low frequency, the result is as follows, for example, when the input frequency is 5 Hz. It is to be noted that the rated frequency is 50 Hz.

Effective value of input voltage=(1/10)Vn

In this case, Vn is a rated voltage. Since the input frequency 5 Hz is one-tenth of the rated frequency 50 Hz, the output from the power generator is also assumed to be one-tenth of that during the operation at the rated frequency. In this case, the sampling interval is also one-tenth of that at a rated frequency, and therefore, set at each electrical angle 3°. Deviation of the input frequency from the rated frequency leads to occurrence of an average error in the maximum half wave.

When the integrated value of the half cycle of the AC voltage is calculated, the result is as follows:

Integrated value of half cycle of AC voltage=(1/10)Vn√2(sin 3+sin 6+. . . +sin 177)=5.39Vn

(the electrical angles for sampling are set at 0°, 3°, 6°, and . . . 177°).

The number of pieces of integrated data is 600 in one second. When the integrated value of the half cycle of the AC voltage is divided by the number of pieces of integrated data, the result is as follows.

(Integrated value of half cycle of AC voltage)/(number of pieces of integrated data)=0.00899Vn

More specifically, an error corresponding to the above-described voltage occurs for each 1 bit. When this error is converted into a circuit voltage, the following is obtained on the condition that a circuit voltage is 10V and the dynamic range of the analog circuit is doubled:

Voltage corresponding to 1-bit error: (10V/2Vn)×0.00899Vn=45 mV

In this case, assuming that AD conversion by the analog-to-digital converter is performed by a 16-bit AD converter, the 1-bit quantum error after AD conversion is as follows:

1-bit quantization error after AD conversion=10V/2¹⁵=0.3 mV

In order to set the voltage (45 mV) corresponding to this 1-bit error to be an about 1-bit quantization error (0.3 mV), the following integration time period is required:

Integration time period=45 mV/0.3 mV=150 seconds

Accordingly, a long integration time period of about several minutes is required for suppressing the above-described half-wave error to be a negligible level. In addition, as to the current value that is input into the digital protection relay, the dynamic range is several tens of times or more, for example, about 50 times. Accordingly, the influence caused by the half-wave error is equal to or less than one-tenth of the error caused by the voltage. Thus, a voltage input will be discussed in the subsequent description.

In contrast, the digital protection relay in the first embodiment calculates and updates an offset voltage value in a relatively short time period of about several seconds also in the case where the input frequency changes, for example, gradually from a low frequency of about 5 Hz to a commercial rated frequency (for example, 50 Hz) with time of several minutes to several tens of minutes.

<Configuration of the First Embodiment>

First, the configuration of a digital protection relay according to the first embodiment will be hereinafter described.

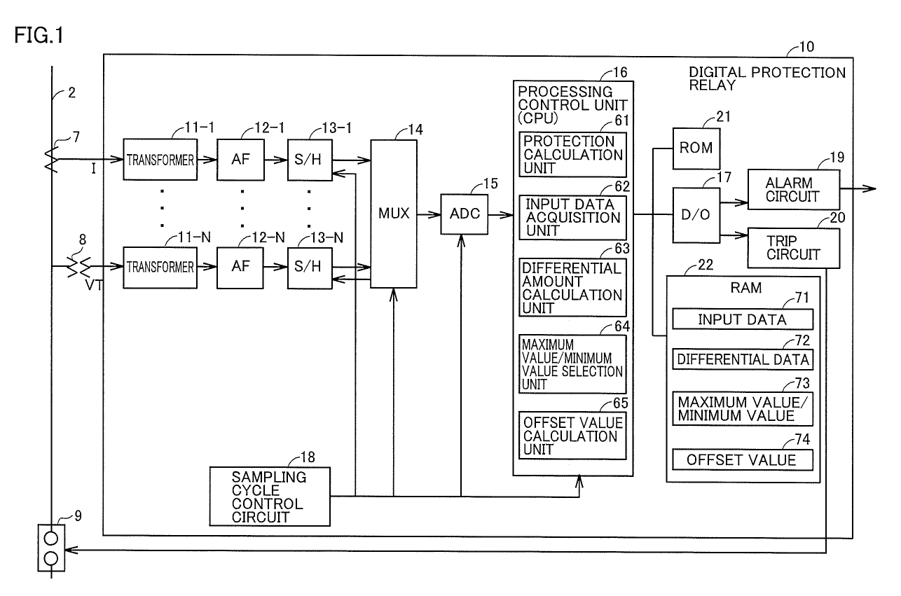

FIG. 1 is a block diagram showing the configuration of a digital protection relay according to the present embodiment. Referring to FIG. 1, a digital protection relay 10 is configured to collect current information and voltage information of the electric power system, and also perform protection relay calculation based on the collected information.

More specifically, digital protection relay 10 includes: a plurality of transformers 11-1 to 11-N (which may be hereinafter collectively referred to as a “transformer 11”); a plurality of analog filters 12-1 to 12-N (which may be hereinafter collectively referred to as an “analog filter 12”); a plurality of sample hold circuits 13-1 to 13-N (which may be hereinafter collectively referred to as a “sample hold circuit 13”); a multiplexer 14; an AD converter 15; a processing control unit 16; a D/O 17; a sampling cycle control circuit 18; an alarm circuit 19; a trip circuit 20; a ROM 21; and a RAM 22.

Furthermore, a power transmission line 2 is provided with a circuit breaker 9, and also provided with a current transformer (CT) 7 and a potential transformer (PT) or a voltage transformer (VT) 8. Current transformer 7 is configured to measure the information (current waveform) about the current flowing through power transmission line 2. Potential transformer/voltage transformer 8 is configured to measure the information (voltage waveform) about the voltage produced in power transmission line 2. Although not shown for convenience of explanation, in the case of a three-phase AC, a potential transformer/voltage transformer may be provided in each phase. The information measured by each of current transformer 7 and potential transformer/voltage transformer 8 is input into digital protection relay 10. In other words, digital protection relay 10 collects the information about the current flowing through power transmission line 2 and the information about the voltage produced in power transmission line 2.

In digital protection relay 10, transformer 11, analog filter 12 and sample hold circuit 13 form an input conversion unit that receives a signal showing the quantity of electricity in the electric power system as an analog signal. Furthermore, as shown in FIG. 1, digital protection relay 10 receives an input of the quantity of electricity in the system through each of a plurality of channels.

Transformer 11 receives analog signals of a current, a voltage and the like from the electric power system, and converts the received signals into a voltage signal suitable for the internal circuit in digital protection relay 10.

Analog filter 12 removes an unnecessary frequency component such as a high frequency noise component that is superimposed on the analog signal input from transformer 11.

Sample hold circuit 13 operates according to the sampling control signal from sampling cycle control circuit 18, receives and holds an input of the signal from analog filter 12, and then, outputs the holding signal to multiplexer 14.

Multiplexer 14 performs time division of signals on N channels output from sample hold circuit 13, and sequentially outputs the resultant signals to AD converter 15. Multiplexer 14 operates according to the sampling control signal from sampling cycle control circuit 18, to select signals extracted from sample hold circuit 13 in a prescribed sampling cycle in order of the channels, and then output the selected signals to AD converter 15.

AD converter 15 sequentially converts, into digital data, N analog input signals that have been time-divided and sequentially output by multiplexer 14.

Processing control unit 16 serves as a processor for controlling the protection calculation by digital protection relay 10 and is formed of a CPU (Central Processing Unit) and the like. Processing control unit 16 operates according to the program stored in ROM 21 or the like, thereby exhibiting functions as a protection calculation unit 61, an input data acquisition unit 62, a differential amount calculation unit 63, a maximum value/minimum value selection unit 64, and an offset value calculation unit 65.

Using the digital data output from AD converter 15, protection calculation unit 61 exhibits a function of performing protection calculation based on the information about the quantity of electricity on power transmission line 2. Protection calculation unit 61 performs protection calculation using an offset value 74.

Input data acquisition unit 62 exhibits a function of: sequentially acquiring the input data converted into a digital signal by AD converter 15 in accordance with the timing shown by a sampling control signal output from sampling cycle control circuit 18; and causing RAM 22 to hold the acquired input data as input data 71.

Differential amount calculation unit 63 exhibits a function of calculating, based on input data 71, the differential amount between the values (for example, voltage values) at each sampling timing. For example, differential amount calculation unit 63 compares the instantaneous value at each sampling timing with the instantaneous value obtained one sample before that, thereby calculating a differential amount between the values at each sampling timing. Differential amount calculation unit 63 exhibits a function of causing RAM 22 to hold the calculation result as differential data 72.

Based on differential data 72, maximum value/minimum value selection unit 64 selects an instantaneous value corresponding to the maximum value and an instantaneous value corresponding to the minimum value from among the input data in each cycle. Based on the amount of change in the differential amount between the sampling values at each sampling timing, maximum value/minimum value selection unit 64 identifies the extreme point at which the polarity of the input data changes, and then, selects the maximal value as the maximum value of the input data in one cycle and the minimal value as the minimum value of the input data in one cycle. Thus, maximum value/minimum value selection unit 64 causes RAM 22 to hold, as a maximum value/minimum value 73, the sampling values of the maximum value and the minimum value that are selected in each cycle.

Offset value calculation unit 65 calculates an offset voltage value based on the maximum value and the minimum value of the sampling values in each cycle. For example, offset value calculation unit 65 uses the average value of the maximum values and the average value of the minimum values in each cycle from among the sampling values, to calculate an average between the average value of the maximum values and the average value of the minimum values as an offset voltage value, and then cause RAM 22 to hold the calculated value as offset value 74.

D/O 17 outputs the result of the protection calculation by processing control unit 16 to the outside of digital protection relay 10. When processing control unit 16 performs protection calculation to monitor the state of the electric power system and detect occurrence of accidents and the like, D/O 17 outputs a trip instruction to trip circuit 20 to perform a protection relay operation, for example, by actuation of circuit breaker 9, and the like. Furthermore, when an abnormality in digital protection relay 10 is detected by the self-diagnosis function performed by processing control unit 16, D/O 17 actuates the output relay in alarm circuit 19 to notify the devices on the outside of digital protection relay 10 about the abnormality in digital protection relay 10.

According to the sampling cycle, sampling cycle control circuit 18 outputs sampling control signals to sample hold circuit 13, multiplexer 14, AD converter 15, and processing control unit 16, to control (i) conversion of the analog signal into digital data and (ii) the timing of protection calculation by processing control unit 16.

ROM 21, which is a nonvolatile storage device, serves to store various data and programs such as a program for operating digital protection relay 10.

RAM 22, which is a volatile storage device, serves to provide a working space used for storing data required for executing a program in processing control unit 16.

<Sampled Data>

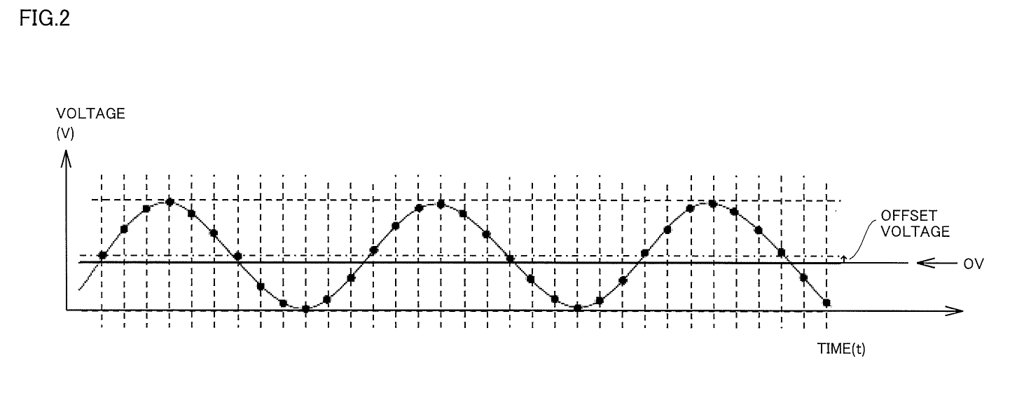

FIG. 2 is a diagram showing the sampling timing and an AC input of a current or a voltage received by digital protection relay 10. The example in FIG. 2 shows the AC input of a rated frequency and also shows that the sampling frequency is 12 times as high as the rated frequency.

In FIG. 2, the vertical dashed line shows sampling timing. FIG. 2 also shows that the offset voltage is on the positive voltage side with respect to 0V of the circuit in digital protection relay 10.

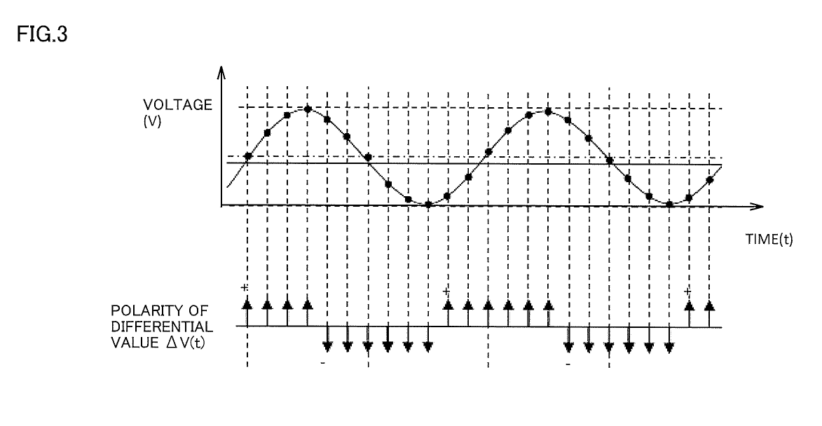

FIG. 3 shows a time period in which a change occurs in the polarity of a differential value ΔV(t) of input data at each sampling timing. In FIG. 3, an upward arrow is shown in the case where differential value ΔV(t) at each sampling timing of the input data is positive while a downward arrow is shown in the case where this differential value ΔV(t) is negative.

In addition, differential value ΔV(t) is defined as follows, for example.

ΔV(t)=V(t)−V(t−1)

In this case, V(t) shows an instantaneous value at time t during a sampling, and V(t−1) shows an instantaneous value obtained one sample before that. In addition, the instantaneous value obtained one sample before that is used in this example for calculating a differential value, but, without limiting thereto, a differential value ΔV(t) may be calculated using the instantaneous value obtained a plurality of samples before that in accordance with the input frequency or the sampling frequency.

As shown in FIG. 3, in the case where the input data is an AC input, the following conditions are established if V(t) is the maximum value.

ΔV(t−2)>ΔV(t−1)>ΔV(t) (wherein ΔV(t) is equal to or greater than zero) and 0>ΔV(t+1)>ΔV(t+2)

Furthermore, when V(t) is the minimum value, the following conditions are established.

ΔV(t−2)<ΔV(t−1)<ΔV(t) (wherein ΔV(t) is equal to or less than zero) and 0<ΔV(t+1)<ΔV(t+2)

Furthermore, when the AC input is zero, the input data contains only an offset voltage. In this case, the maximum value and the minimum value of input data are almost the same value, and thus, the above-described conditions are not established. In this case, the differential value at each timing of sampling of the input data is equal to or less than a predetermined value.

Furthermore, when it is determined that a failure occurs in the system, digital protection relay 10 stops the above-described determination about the maximum value and the minimum value of the sampling values, and continuously uses the offset value used before the determination about a failure. Furthermore, when the time period with no calculation of the maximum value and the minimum value of the sampling values continues for a certain time period or more, digital protection relay 10 determines it as an abnormal input, and causes alarm circuit 19 to output an alarm to a device on the outside of digital protection relay 10.

<Operation in the First Embodiment>

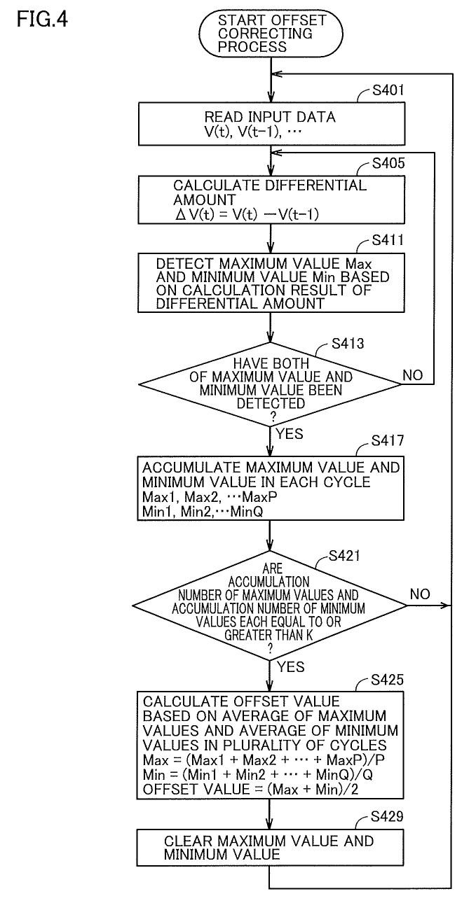

FIG. 4 is a flowchart showing a process of correcting an offset value by digital protection relay 10.

In step S401, processing control unit 16 of digital protection relay 10 reads input data (V(t), V(t−1), . . . ) converted by AD converter 15 into digital data. In the first embodiment, assuming that differential value ΔV(t) between the sampling values is calculated using the instantaneous value obtained one sample before that, the input data in a plurality of cycles is read in step S401.

In step S405, processing control unit 16 uses the instantaneous value one sample before that to calculate a differential value ΔV(t) between the sampling values (ΔV(t)=V(t)−V(t−1)).

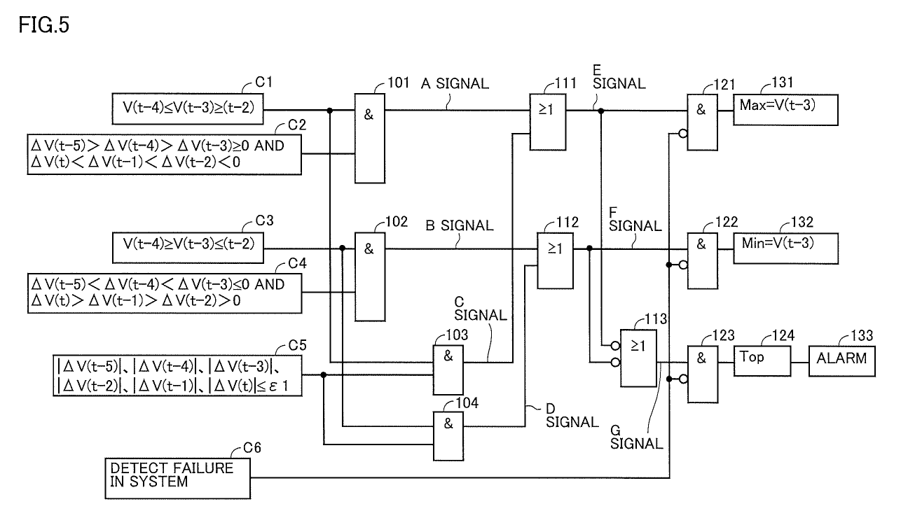

In step S411, based on the calculation result of differential value ΔV(t) at each sampling timing, processing control unit 16 calculates an amount of change in differential value ΔV(t) and identifies a sampling value at which the amount of change changes from positive to negative or negative to positive. Processing control unit 16 identifies the sampling value at the timing at which the polarity of the differential amount changes, thereby detecting the maximum value and the minimum value of the sampling values in one cycle. This process will be described later with reference to FIG. 5.

In step S413, it is determined whether both of the maximum value and the minimum value of the sampling values have been detected or not. If both of the maximum value and the minimum value have been detected, the process proceeds to step S417 (YES in step S413). If not (NO in step S413), the process in step S405 is carried out.

In step S417, processing control unit 16 accumulates, in RAM 22, the maximum value and the minimum value of the sampling values in each cycle as a maximum value/minimum value 73.

In step S421, processing control unit 16 determines whether the accumulation number of the maximum values of the sampling values and the accumulation number of the minimum values of the sampling values each are equal to or greater than a predetermined number (K) or not. If each accumulation number is equal to or greater than the predetermined number (YES in step S421), the process in step S425 is carried out. If not (NO in step S421), the process in step S401 is carried out. In step S425, processing control unit 16 calculates an average of the maximum values of the sampling values and an average of the minimum values of the sampling values, sums the average of the maximum values and the average of the minimum value, and then divides the summed result by 2 (averaging), thereby calculating an offset value. Then, processing control unit 16 causes RAM 22 to hold this offset value as an offset value 74. This offset value is used for protection calculation by processing control unit 16 until the next offset value is calculated.

In step S429, processing control unit 16 clears the maximum value and the minimum value in each cycle that are accumulated in 73, and then carries out the process in step S401.

Referring to FIG. 5, the process in step S411 will be hereinafter described in detail.

FIG. 5 is a diagram showing a process for detecting a maximum value and a minimum value from among sampling values.

(1) When a logical AND 101 of a condition C1 and a condition C2 is established for the input data having been read in step S401, processing control unit 16 outputs a signal A showing that a voltage value V(t−3) is a maximum value.

(2) When a logical AND 102 of a condition C3 and a condition C4 is established, processing control unit 16 outputs a signal B showing that a voltage value V(t−3) is a minimum value.

(3) When a logical AND 103 of a condition C1 and a condition C5 is established, processing control unit 16 outputs a signal C showing the maximum value obtained in the case where the AC signal as input data is minute or a zero input.

(4) When a logical AND 104 of a condition C3 and a condition C5 is established, processing control unit 16 outputs a signal D showing the minimum value obtained in the case where the AC signal as input data is minute or a zero input.

(5) A condition C5 shows that an absolute value of the differential value between the sampling values is a constant value ε1 over a plurality of samples. In this case, this constant value ε1 is assumed to be a value greater than the differential value between the sampling values caused by fluctuations of data in the case where the input data is a zero input. In this way, it is determined whether the AC signal as input data is minute or a zero input.

(6) A condition C6 shows that a failure has been detected in the system.

(7) When a logical AND 121 is satisfied in the cases: where a signal E as a logical OR 111 of a signal A and a signal C is input; and where a condition C6 is not established, processing control unit 16 detects a maximum value (voltage value V(t−3)).

(8) When a logical AND 122 is satisfied in the cases: where a signal F as a logical OR 112 of a signal B and a signal D is input; and where a condition C6 is not established, processing control unit 16 detects a minimum value (voltage value V(t−3)).

(9) When signal E and signal F are not output (logical OR 113) and condition C6 is not established (logical AND 123), a timer starts counting. Then, when the counted value reaches a certain value (Top 124), processing control unit 16 outputs an alarm (alarm 133). Processing control unit 16 outputs this alarm at the time when the offset value is not measured for a certain time period or more. In this way, the maximum value and the minimum value are selected based on the sampling values.

<Summary of the First Embodiment>

The following is an explanation about calculation of the offset value and an example of sampling performed when a low-frequency input signal is received in digital protection relay 10 of the first embodiment.

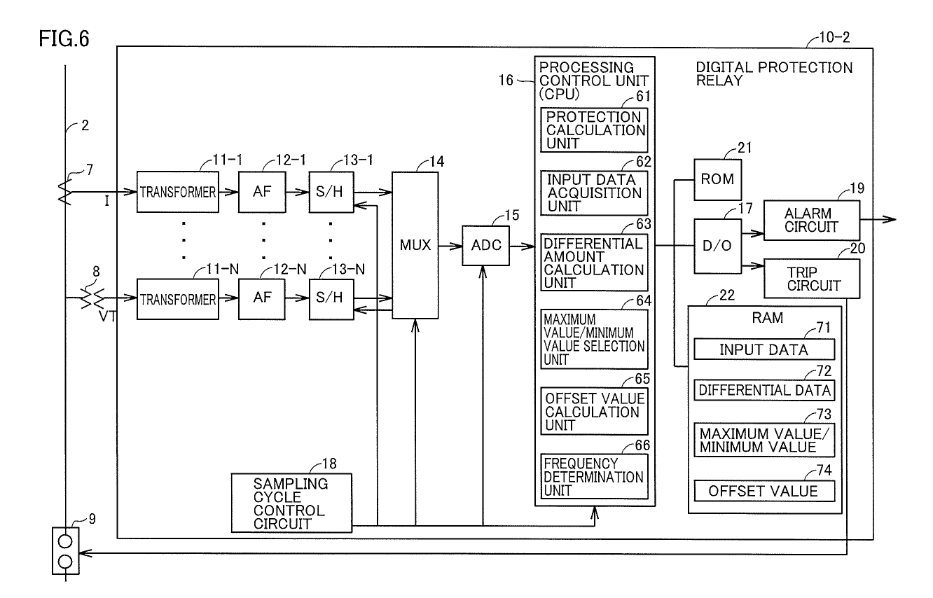

FIG. 6 is a diagram showing an example of sampling at a low frequency. For example, it is assumed that the rated frequency is set at 50 Hz, and the frequency of a low-frequency AC input is set at 5 Hz.

On the condition that the AC input is one-tenth of the rated frequency (a low frequency of 5 Hz with respect to the rated frequency of 50 Hz), when sampling is performed, for example, at an electrical angle 30° at the rated frequency (the sampling frequency is 600 Hz), the electrical angle becomes 3° at a low frequency. Also in this case, processing control unit 16 can detect the maximum value and the minimum value of the sampling values by performing operations in FIGS. 4 and 5, and also can calculate an offset value using these maximum value and minimum value.

For example, even if the AC input is a low frequency of 5 Hz, and for example, even if the accumulation number of each of the maximum values and the minimum values is selected to be about 10 (K=10), processing control unit 16 can calculate an offset value based on the maximum value and the minimum value of the sampling values in a time period of about 2 seconds. Furthermore, when the frequency approaches a rated frequency (50 Hz), the time period of one cycle reaches 20 ms (1 second/50). Thus, even if the accumulation number of each of the maximum values and the minimum values is selected to be about 10 (K=10), processing control unit 16 can calculate an offset value in a time period of about 0.2 seconds (20 ms×10), so that the process for calculating and updating the offset value can be shortened. Also, unlike the related art, a half-wave error does not occur.

### Second Embodiment

Then, a digital protection relay 10-2 in the second embodiment will be hereinafter described.

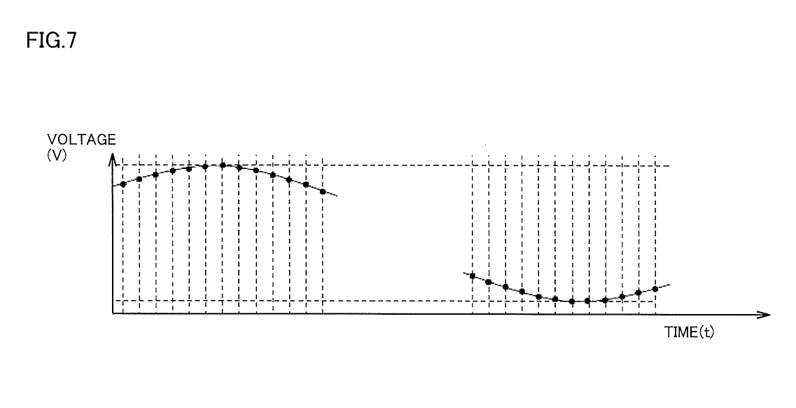

FIG. 7 is a diagram showing the configuration of digital protection relay 10-2 in the second embodiment. When comparing this digital protection relay 10-2 in the second embodiment with digital protection relay 10 in the first embodiment, processing control unit 16 includes a frequency determination unit 66, and determines whether the frequency of the input data is a rated frequency or is equal to or less than a prescribed frequency lower than the rated frequency. Then, according to the determination result, processing control unit 16 controls the time interval between the sampling values used for calculating the differential amount between the sampling values. For example, when it is determined that the frequency of the input data is a low frequency, processing control unit 16 calculates the amount of change in the differential amount in the state where the time interval between the sampling values used for calculating a differential amount is increased.

For example, assuming that the electrical angle of sampling is 30° at a rated frequency of 50 Hz, the electrical angle of sampling becomes 3° when the AC input is 5 Hz. Thus, the differential amount between the sampling values is decreased, so that highly accurate calculation is required. Accordingly, when the AC input frequency decreases, the sampling value used for calculating a differential amount is set at a sampling value obtained a plurality of sampling values before that, thereby eliminating the need of highly accurate calculation.

<Operation of the Second Embodiment>

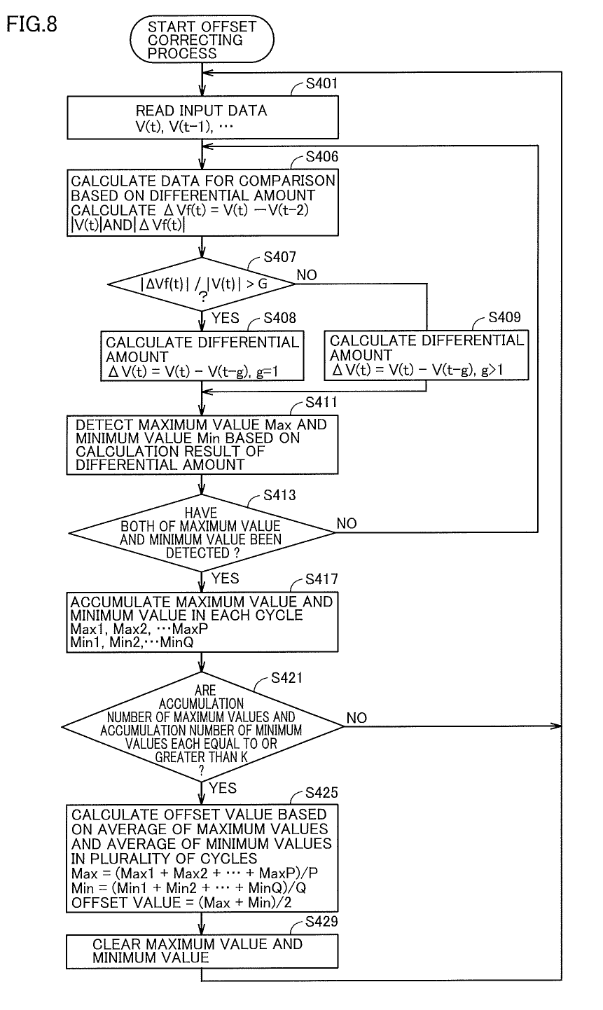

FIG. 8 is a flowchart illustrating an operation of digital protection relay 10-2 in the second embodiment.

In step S406, processing control unit 16 performs calculation of ΔVf(t)=V(t)−V(t−2), |V(t)|, and |ΔVf(t)|. In this case, ΔVf(t)=V(t)−V(t−2) shows that the sampling value is compared with the sampling value obtained two samples before that, thereby calculating a differential value. Also, |V(t)| shows the amplitude of V(t). In this case, ΔVf(t) is a difference from the data obtained two samples before that. Accordingly, assuming that the rated frequency is 50 Hz, processing control unit 16 calculates, as a differential amount, the difference from the data obtained an electrical angle 60° before that.

In step S407, depending on whether |ΔVf(t)|/|V(t)| is greater than a constant G or not, processing control unit 16 determines whether the AC input frequency is a low frequency or not.

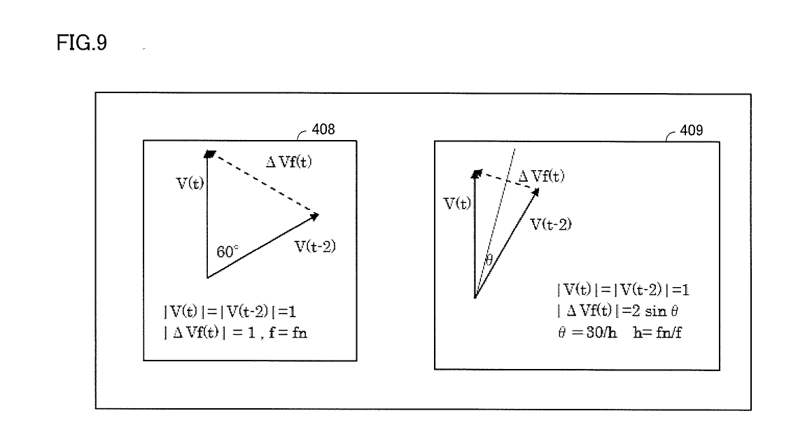

FIG. 9 is a diagram showing the relation between an electrical angle and the magnitude of a differential amount between the sampling values. As shown in FIG. 9, assuming that the rated frequency is 50 Hz, the result is obtained as |V(t)|=|ΔVf(t)| (relation 408). The sampling cycle is constant. Accordingly, when the AC input frequency decreases, the following relation is established between the frequency and the differential amount.

(1) In the case of a rated frequency (frequency f=fn (rated frequency)) (relation 408):

|ΔVf(t)|/|V(t)|=1

(2) In the case of a low frequency (frequency f=fn/h) (relation 409):

|ΔVf(t)|/|V(t)|=2 sin (30/h)

For example, in the case where |ΔVf(t)|/|V(t)|=0.3, the result will be h=3.5, that is, the low frequency is 14.4 Hz with respect to the rated frequency of 50 Hz.

In the case where constant G=0.3 is selected in step S407 in FIG. 8, if the frequency is greater than 14.4 Hz (YES in step S407), processing control unit 16 causes the process to proceed to step S408. If not (NO in step S407), processing control unit 16 causes the process to proceed to step S409.

In step S408, in order to calculate a differential amount between the sampling values, processing control unit 16 compares the current sampling value with the sampling value obtained one sample before that on the condition that a value g=1, thereby calculating a differential amount.

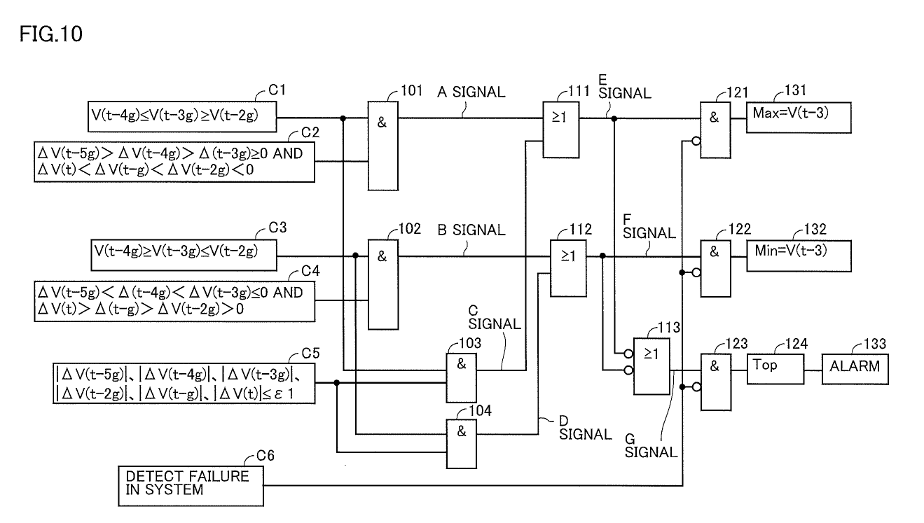

In step S409, in order to calculate a differential amount between the sampling values, processing control unit 16 compares the current sampling value with the sampling value obtained g samples before that on the condition that a value g is greater than 1, thereby calculating a differential amount. In this example, since the switching point of the frequency is 14.4 Hz, the largest value that can be set as a value g is 3. For example, assuming that value g=3, processing control unit 16 uses ΔV(t) to ΔV(t−5×3) as ΔV in the determination process in FIG. 10. Accordingly, V(t) to V (t−6×3) is used as input data V in the determination process in FIG. 10. In other words, in order to calculate a differential amount between the sampling values, processing control unit 16 uses an instantaneous value obtained 18 samples before that. When the instantaneous value obtained 18 samples before that is used, the result is as follows: 30°×(14.5/50)×18=155°. Thus, processing control unit 16 calculates, as a differential amount, the difference from the data obtained an electrical angle 155° before that. In other words, the difference is calculated for the data about an electrical angle of 180° or less. In this case, similarly assuming that value g=4, processing control unit 16 is to calculate a differential amount between the sampling values using an instantaneous value obtained 24 samples before that. The result is as follows: 30°×(14.4/50)×24=207°, in which case the instantaneous value of a half period or more of the input waveform cannot be determined by the determination about the maximum value and the minimum value using V(t). Thus, the maximum value of value g is 3. Therefore, the value that can be set as a value g is 2 or 3 in this example.

In step S411, processing control unit 16 detects the maximum value and the minimum value of the sampling values according to each of conditions shown in FIG. 10. FIG. 10 is a diagram showing a process for detecting the maximum value and the minimum value from among the sampling values.

<Summary of the Second Embodiment>

As described above, when the frequency input into digital protection relay 10-2 is in a low frequency band, the time difference between the sampling data used for calculating a difference between the sampling values is expanded, so that the reliability of the operation in a low frequency band can be improved. In the second embodiment, there are two separate frequency bands including: a frequency band close to a rated frequency; and a low frequency band, but there may be further separated frequency bands. Thereby, the reliability of the operation of digital protection relay 10-2 can be improved.

It should be understood that the embodiments disclosed herein are illustrative and non-restrictive in every respect. The scope of the present invention is defined by the terms of the claims, rather than the description above, and is intended to include any modifications within the meaning and scope equivalent to the terms of the claims.

### REFERENCE SIGNS LIST

2 power transmission line,
9 circuit breaker,
7 current transformer,
8 potential transformer,
10 digital protection relay,
11 transformer,
12 analog filter,
13 sample hold circuit,
14 multiplexer,
15 AD converter,
16 processing control unit,
17 D/O,
18 sampling cycle control circuit,
19 alarm circuit,
20 trip circuit,
21 ROM,
22 RAM,
61 protection calculation unit,
62 input data acquisition unit,
63 differential amount calculation unit,
64 maximum value/minimum value selection unit,
65 offset value calculation unit,
71 input data,
72 differential data,
73 maximum value/minimum value,
74 offset value.

1. A digital protection relay comprising:
an input conversion unit configured to receive a signal showing a quantity of electricity in an electric power system as an analog signal;
an analog-to-digital conversion unit configured to convert the analog signal into a digital signal; and
a control unit configured to perform protection calculation based on the digital signal,
the control unit including
a protection calculation unit configured to perform the protection calculation using an offset voltage value,
an acquisition unit configured to sequentially acquire input data, which is converted into a digital signal by the analog-to-digital conversion unit, in accordance with sampling timing, and
an offset value calculation unit configured to calculate the offset voltage value based on sampling values at a timing at which a change occurs in a polarity of a differential amount among the input data in at least one cycle, the timing being specified based on the differential amount between the sampling values.

2. The digital protection relay according to claim 1, wherein
the control unit includes a selection unit configured to select a sampling value corresponding to a maximum value and a sampling value corresponding to a minimum value from among the input data in at least one cycle by identifying an extreme point of the input data based on an amount of change in the differential amount, and
the offset value calculation unit is configured to calculate the offset voltage value based on the sampling value corresponding to the maximum value and the sampling value corresponding to the minimum value.

3. The digital protection relay according to claim 2, wherein the offset value calculation unit is configured to calculate, as the offset voltage value, an average value between the sampling value corresponding to the maximum value and the sampling value corresponding to the minimum value.

4. The digital protection relay according to claim 2, wherein
the selection unit is configured to select, from among the input data in a plurality of cycles, the sampling value corresponding to the maximum value and the sampling value corresponding to the minimum value in each of the plurality of cycles, and
the offset voltage value is calculated based on an average of the sampling values corresponding to the maximum values in the plurality of cycles and an average of the sampling values corresponding to the minimum values in the plurality of cycles.

5. The digital protection relay according to claim 1, wherein the control unit is configured to output an alarm when at least one of (i) a time period in which the sampling value corresponding to a maximum value is not detected and (ii) a time period in which the sampling value corresponding to a minimum value is not detected reaches a predetermined time period.

6. The digital protection relay according to claim 2, wherein the selection unit is configured to detect that the input data is a zero input or a minute AC input based on an absolute value of the amount of change in the differential amount, and compare magnitudes of the sampling values at each sampling timing when the input data is a zero input or a minute AC input, thereby selecting the sampling value corresponding to the maximum value and the sampling value corresponding to the minimum value.

7. The digital protection relay according to claim 1, wherein the control unit includes
a frequency determination unit configured to determine whether a frequency of the input data is a rated frequency or a frequency lower than the rated frequency; and
a differential amount calculation unit configured to calculate an amount of change in the differential amount by controlling a time interval between the sampling values for calculating the differential amount between the sampling values according to a determination result of the frequency.
